(19) United States
(12) Patent Application Publication
(10) Pub. No.: US 2019/0379394 A1
(43) Pub. Date: Dec. 12, 2019

(54) SYSTEM AND METHOD FOR GLOBAL DATA COMPRESSION

(71) Applicant: Vast Data Ltd., Tel Aviv (IL)

(72) Inventors: Renen HALLAK, Tenafly, NJ (US); Asaf LEVY, Tel Aviv (IL); Shachar FIENBLIT, Ein Ayala (IL); Niko FARHI, Petach Tikva (IL); Noa COHEN, Tel Aviv (IL)

(73) Assignee: Vast Data Ltd., Tel Aviv (IL)

(21) Appl. No.: 16/002,880

(22) Filed: Jun. 7, 2018

(51) Int. Cl. H03M 7/30; G06F 17/30

(52) U.S. Cl. CPC H03M 7/3091; G06F 17/30097; G06F 17/30153

(57) ABSTRACT

A system and method for global data compression. The method includes splitting a dataset into a plurality of blocks; for each block of the plurality of blocks: computing at least one similarity hash for the block; determining, based on the at least one similarity hash, whether a similar block is found for the block, wherein a similar block for a block has a similarity hash that is similar to one of the computed at least one similarity hash for the block; compressing the block by replacing data of the block with a reference to the similar block and a delta when a similar block is found, wherein the delta is a difference in data between the block and the similar block; and compressing the block independently when a similar block is not found.

### TECHNICAL FIELD

The present disclosure relates generally to data reduction, and more specifically to reducing effective capacity costs via data reduction.

### BACKGROUND

Due to advances in increasing adoption of computer technologies, the amount of computer data that must be stored is increasing exponentially. With growth in the amount of data being stored comes a need to minimize costs of storing the increasing amount of data. To address this need, various techniques for data reduction have been developed. Among these techniques are compression and deduplication, each of which may reduce the total size of stored data.

Compression involves encoding data into a format that uses fewer bits than an original format of the data. When encoding data in a file, unnecessary data is removed. For example, the unnecessary data may be redundant data within the file. Compression is a local process that reduces data with fine granularity within each file but does not account for redundancies among different files.

Deduplication involves eliminating redundant files or relatively large sections of files. For example, entire duplicated blocks may be removed. To reduce the amount of redundant data, deduplication typically includes storing a single copy of the duplicated block along with references to the block rather than additional copies. Deduplication is a global process that reduces data with coarse granularity among different files but does not generally account for redundancies within each file. Also, deduplication requires exact copies of blocks or files for identifying redundant data. As a result, misalignment of copies (e.g., when new data is added before the end of a block but not to otherwise identical copies of the block) results in failure to identify some redundancies.

Different data storage systems using existing data reduction solutions may have the best result when using different techniques (e.g., compression rather than deduplication or vice-versa) or when using multiple techniques (e.g., both compression and deduplication). However, for most systems, each of these options has drawbacks. As an example for chunked data, deduplication is more efficient when data is chunked into smaller chunks, while compression is more efficient when data is chunked into larger chunks. When multiple data reduction techniques are used, computing resources such as CPU power increase. This results in a need for more expensive hardware in order to accommodate the increased workload.

Additionally, combinations of existing data reduction solutions such as deduplication then compression may also fail to compress all similar data. As a result, at least some redundant data may not be removed. For example, logs may contain repetitive data that may not be identified as redundant. As another example, bitmap pictures with minor differences (e.g., one picture is a slightly modified version of the other) may not be identified as including redundant data.

It would therefore be advantageous to provide a solution that would overcome the challenges noted above.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Certain embodiments disclosed herein include a method for global data compression. The method comprises: splitting a dataset into a plurality of blocks; for each block of the plurality of blocks: computing at least one similarity hash for the block; determining, based on the at least one similarity hash, whether a similar block is found for the block, wherein a similar block for a block has a similarity hash that is similar to one of the computed at least one similarity hash for the block; compressing the block by replacing data of the block with a reference to the similar block and a delta when a similar block is found, wherein the delta is a difference in data between the block and the similar block; and compressing the block independently when a similar block is not found.

Certain embodiments disclosed herein also include a non-transitory computer readable medium having stored thereon causing a processing circuitry to execute a process, the process comprising: splitting a dataset into a plurality of blocks; for each block of the plurality of blocks: computing at least one similarity hash for the block; determining, based on the at least one similarity hash, whether a similar block is found for the block, wherein a similar block for a block has a similarity hash that is similar to one of the computed at least one similarity hash for the block; compressing the block by replacing data of the block with a reference to the similar block and a delta when a similar block is found, wherein the delta is a difference in data between the block and the similar block; and compressing the block independently when a similar block is not found.

Certain embodiments disclosed herein also include a system for global data compression. The system comprises: a processing circuitry; and a memory, the memory containing instructions that, when executed by the processing circuitry, configure the system to: split a dataset into a plurality of blocks; for each block of the plurality of blocks: compute at least one similarity hash for the block; determine, based on the at least one similarity hash, whether a similar block is found for the block, wherein a similar block for a block has a similarity hash that is similar to one of the computed at least one similarity hash for the block; compress the block by replacing data of the block with a reference to the similar block and a delta when a similar block is found, wherein the delta is a difference in data between the block and the similar block; and compress the block independently when a similar block is not found.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is a flowchart illustrating a method for global data compression according to an embodiment.

FIG. 2 is a flowchart illustrating a method for normalizing data according to an embodiment.

FIG. 3 is a network diagram utilized to illustrate deployment of compute nodes configured according to various disclosed embodiments.

FIG. 4 is a schematic diagram of a compute node according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

The various disclosed embodiments include a method and system for global compression of data. The data is stored in one or more storage devices. In some embodiments, data is normalized to allow for comparing among data that was compressed when in different file formats. The data is split into blocks using variable-size chunking. Similarity hashing is performed to identify similar blocks and a reference block is selected among each group of similar blocks. The reference blocks are stored normally. Similar blocks are removed and replaced with references to their respective reference blocks and deltas including non-redundant data. The remaining data is compressed and stored.

The disclosed embodiments include a system and method for global compression of data that demonstrates fine granularity, i.e., granular with respect to bytes of data rather than blocks or files. The global compression reduces effective capacity costs for storage systems. Additionally, some embodiments include techniques for minimizing numbers of reads for data that is reduced via global compression.

Example uses of the disclosed embodiments include reducing sizes of data in storage systems storing data such as, but not limited to, multimedia content (e.g., images, videos, etc.), genome data, financial data (e.g., stock data), medical data (e.g., medical images), and the like. These types of data may include redundant data featuring minor differences that may not be identified for reduction according to existing solutions. The disclosed fine granularity compression techniques allow for reducing such redundant data.

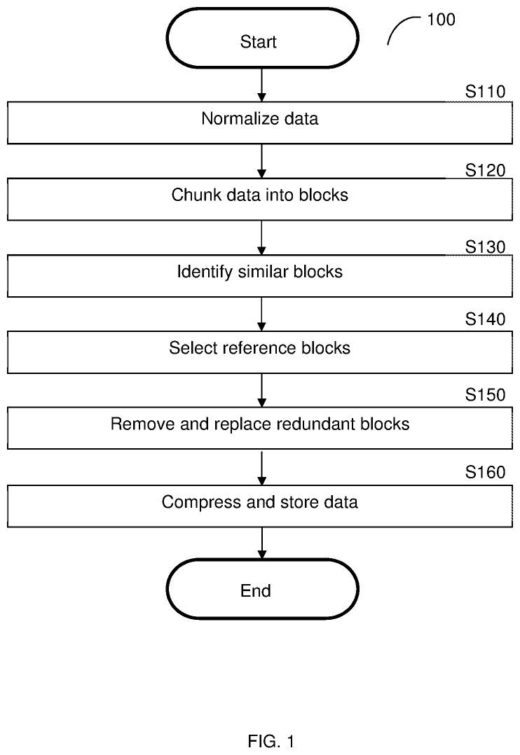

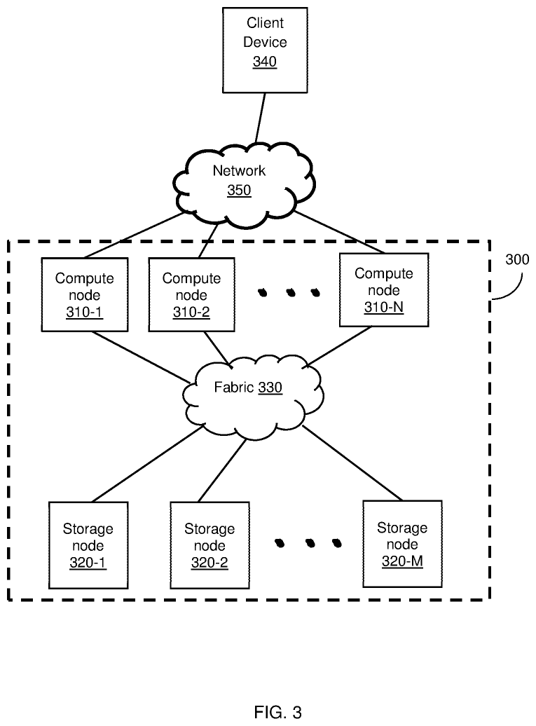

FIG. 1 shows an example flowchart illustrating a method for global compression of data according to an embodiment. The data may be stored in one or more storage nodes, for example the storage nodes 320 discussed herein below with respect to FIG. 3.

In an example implementation, the global compression may be performed as a background process of a storage system (e.g., the storage system 300, FIG. 3). For example, data may be initially stored in an uncompressed or locally compressed manner, and the method may be performed on the data during normal operation of the storage system. The data to be globally compressed may be static or may be dynamically changing during operation of the storage system.

In an embodiment, the method may be performed by a compute node (e.g., one of the compute nodes 310, FIG. 3). The compute node may include a calling module configured to perform the method and a metadata module configured to generate metadata to be stored with the compressed data as well as to respond to queries and to update the metadata. Each module may store a copy of any data structures used for accessing a location in storage. For example, when the data structures include an array and a tree (e.g., a B-tree), each module may store a copy of the array and the tree.

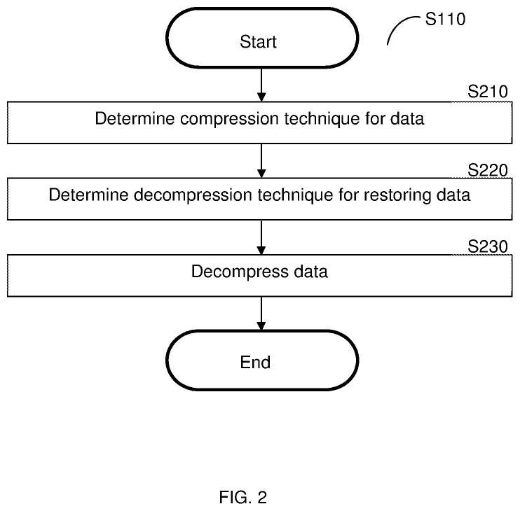

At optional S110, data to be reduced is normalized prior to being globally compressed. The normalization may allow for comparing data that originally existed in different file formats. The data to be normalized may include, for example, newly received data to be compared and reduced with respect to previously stored data. In some embodiments, normalizing the data may include decompressing compressed data. An example normalization process is described further herein below with respect to FIG. 2.

At S120, the data is split into blocks. In an embodiment, the data is chunked using variable-size chunking such that blocks are split according to content of the data rather than a logical offset. For example, the variable-size chunking may include using a rolling hash (e.g., the Rabin hash) to find break points with respect to an average block size.

In an embodiment, splitting the data includes creating splitting criteria by hashing a sliding window of a file and cutting the file when the hash matches a mask (e.g., when the last 13 bits of the mask are 0). In some implementations, the data is split to meet minimum and maximum numbers of bytes so that blocks are not too long or too short. For example, for data having a mask with k bits, the minimum number of bytes may be 2^{k-1} and the maximum number may be 2^{k+1}.

At S130, the blocks are compared to identify similar blocks. In an embodiment, S130 includes using similarity hashing to compare each block to each other block. Specifically, one or more similarity hashes is computed for each block and the computed similarity hashes are compared among blocks. If two datasets are similar (i.e., their Levenshtein distance is below a threshold), there is a high likelihood that their similarity hashes will be the same. Similarly, if a Jaccard distance between blocks is below a threshold, the blocks are likely to be similar. Thus, when two blocks have the same similarity hash, the two blocks may be identified as similar. As a result, the size of a compressed block including data from two similar blocks is significantly smaller than the total size of the blocks compressed separately. Blocks identified as similar to each other may be clustered into sets of similar blocks.

In an embodiment, S130 includes determining, for each block, whether a similar block can be found. The similar block may be found among incoming blocks, previously stored blocks, or among both incoming and previously stored blocks. When a similar block is found, the block may be compressed using a process including selecting a reference block and replacing redundant blocks as described with respect to S140 and S150. Otherwise, the block may be compressed independently without reference to another block.

In an embodiment, the process used for chunking the data at S120, the type of similarity hash used at S130, or both, may depend on a type of data being compressed. Example types of data may include, but are not limited to, genome data, stock data, multimedia data, and the like. Different methods for chunking or comparing data may produce better (e.g., more accurate or more efficient) results for different types of data. The similarity hash used may include, but is not limited to, simhash, minhash, idhash, and the like. In another example implementation, multiple types of similarity hashes may be utilized, for example both simhash and idhash.

At S140, reference blocks are selected from among each set of similar blocks. In an embodiment, one reference block is selected for each set of similar blocks. Each non-selected block is a redundant block with respect to one of the selected reference blocks, i.e., each redundant block is similar to a respective reference block as described above. In an example implementation, each reference block is the first block written to a storage from the group of similar blocks, i.e., a block that was written before other blocks of the set. In another example implementation, each reference block may be the longest block, or the block having the largest size, among the respective set of similar blocks. In other implementations, the reference blocks may be selected based on different criteria.

At S150, redundant blocks are removed and replaced. In an embodiment, each redundant block is replaced with a reference to its respective similar reference block and a delta including data included in the redundant block that is not redundant with data of the reference block. Replacing redundant blocks with references and deltas provides fine granularity (e.g., with respect to blocks rather than larger datasets) but global effects among stored data.

At S160, the remaining data is compressed and stored. Compressing the remaining data may include compressing the deltas of redundant blocks, compressing data that was not replaced with a reference, or both. Because redundant blocks are replaced with references to similar blocks, the redundant blocks may be compressed as if they were appended to their respective reference blocks and the compression ratio is increased as compared to compressing the blocks separately. The compression may be based on lossless compression algorithms such as, but is not limited to, delta encoding, Lempel-Ziv, and the like. Any blocks for which similar blocks were not found may be compressed independently, i.e., by using a compression algorithm on data of the block without adding a reference to another block.

In an embodiment, portions of the compressed data are stored with respective metadata. The metadata may be utilized to subsequently access and decompress the compressed data, and may include, but is not limited to, a physical offset (i.e., with respect to a location in a storage), an uncompressed data length, a compressed data length, a reference count, a reference block identifier, a compression algorithm used to compress the data, combinations thereof, and the like. In an embodiment, the reference count is a number of identical or similar instances of the data that is increased each time an identical or similar chunk of data is identified, e.g., as described at S130. The reference count may be utilized to, among other things, determine when to delete references to the data (for example, when the reference count is 0) without requiring additional comparisons of the data itself.

In an embodiment, the metadata for a portion of data includes the compression algorithm used when the portion of data was not replaced with a reference to a reference block. In an example implementation, the metadata may be included in an element store as described further in U.S. patent application Ser. No. 16/002,804, assigned to the common assignee, the contents of which are incorporated by reference. To this end, the metadata to be included with the compressed data may be generated by one of the compute nodes 310 described further with respect to FIG. 3.

The data may be mapped using a data structure mapping similarity hashes to locations in storage, thereby allowing for indexing by similarity hash for efficient access. To this end, in an embodiment, such a data structure may include an array and a B-tree with operation cache. In an example implementation, each physical block of data in storage will be assigned a serial number, where the array includes serial numbers as keys and values of locations in storage (e.g., physical offsets) to allow for fast access to data during reading and can be accessed independently of the B-tree. The B-tree is a leveled tree having an operation cache in the nodes that is used to locate similar data when new data is written. Each internal node in the tree include keys that serve as indices. The keys may include similarity hash values computed for the corresponding data to which the key is mapped. In an example implementation, the tree is navigated using binary search on the keys at each level of the tree.

The method of FIG. 1 may be repeated when new data is received. The new data may be compared to stored data as described with respect to S130 through S160 such that redundant data (i.e., redundant with respect to previously stored data) among the new data is replaced with appropriate references. For example, when new data is received, the new data may be chunked into blocks and a similarity hash may be computed for each block of the new data. The new data block similarity hashes may be compared to similarity hashes stored as metadata for previously stored data.

It should be noted that the embodiment described with respect to FIG. 1 may be performed on data blocks stored in different storage devices (e.g., the storage nodes 320, FIG. 3) in order to remove redundant data both in each storage device and across the storage devices (i.e., data having copies stored in multiple storage devices). In some implementations, one or more copies of each reference block may not be removed and may be retained to allow for redundancy in case of failure of a storage device including the reference block.

FIG. 2 is an example flowchart S110 illustrating a method for normalizing data according to an embodiment. The normalization allows for comparing compressed data while preserving similarities in the original data. For example, gzip is not similarity preserving, i.e., the post-compression data may not be similar even if the original data is similar. Thus, comparing incoming data to previously compressed data may fail to identify at least some instances of redundant data.

At S210, a compression technique used to compress data to be compared is determined. In an embodiment, S210 includes identifying metadata associated with the compressed data and determining the compression technique indicated in the identified metadata. The identified metadata may be stored with the compressed data and read from a location in storage of the compressed data. At S220, a decompression technique for restoring the compressed data is determined based on the determined compression technique. At S230, the data is decompressed using the determined decompression technique. Decompressing data to be compared allows for preserving similarity of compressed data even when the compression techniques used to compress the data may result in differences in compressing the same data, for example when the same data is stored in different file formats and compressing the data in the different file formats results in different compressed data.

FIG. 3 is an example network diagram illustrating an example deployment of a storage system 300 configured for global data compression according to various disclosed embodiments. The storage system 300 includes a number of N compute nodes 310-1 through 310-N (hereinafter referred to individually as a compute node 310 and collectively as compute nodes 310, where N is an integer equal to or greater than 1) and a number of M storage nodes storage nodes 320-1 through 320-M (hereinafter referred to individually as a storage node 320 and collectively as storage nodes 320, where M is an integer equal to or greater than 1). The compute nodes 310 and the storage nodes 320 communicate through a communication fabric 330.

A compute node 310 may be realized as a physical machine or a virtual machine. A physical machine may include a computer, a sever, and the like. A virtual machine may include any virtualized computing instance (executed over a computing hardware), such as a virtual machine, a software container, and the like.

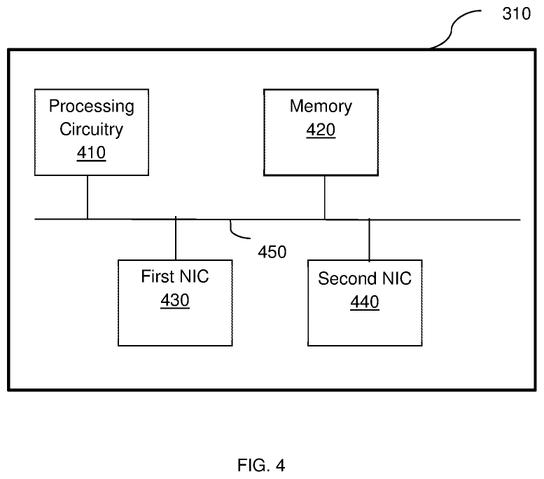

It should be noted that in both configurations (physical or virtual), the compute node 310 does not require any dedicated hardware. An example arrangement of a compute node 310 is provided in FIG. 4.

A compute node 310 is configured to perform tasks related to the management of the storage nodes 320. In an embodiment, each compute node 310 interfaces with a client device 340 (or an application installed therein) via a network 350. To this end, a compute node 310 is configured to receive requests (e.g., read or write requests) and promptly serve these requests in a persistent manner. The network 350 may be, but is not limited to, the Internet, the world-wide-web (WWW), a local area network (LAN), a wide area network (WAN), and the like.

Each compute node 310 is configured to interface with different protocols implemented by the client devices 340 or applications (e.g., HTTP, FTP, etc.) and to manage the read and write operations from the storage nodes 320. The compute node 310 is further configured to translate the protocol commands into a unified structure (or language). Then, each compute node 310 is also configured to logically address and map all elements stored in the storage nodes 320.

In an embodiment, each compute node 310 is further configured to perform global compression as described further herein above on data stored in the storage nodes 320. The global compression allows for removing redundant data among the storage nodes 320.

The storage nodes 320 provide the storage and state in the storage system 300. To this end, each storage node 320 may include, for example, a plurality of SSDs. The storage nodes 320 may be configured to have the same capacity as each other or different capacities from each other. Each storage node 320 may include a non-volatile random-access memory (NVRAM) and an interface module (not shown) for interfacing with the compute nodes 310.

The storage node 320 communicates with the compute nodes 310 over the communication fabric 330. It should be noted that each compute node 310 can communicate with each storage node 320 over the communication fabric 330. There is no direct coupling between a compute node 310 and storage node 320.

The communication fabric 330 may include an Ethernet fabric, an Infiniband fabric, and the like. Specifically, the communication fabric 330 may enable communication protocols such as, but not limited to, remote direct memory access (RDMA) over Converged Ethernet (RoCE), iWARP, Non-Volatile Memory Express (NVMe), and the like. It should be noted that the communication protocols discussed herein are provided merely for example purposes, and that other communication protocols may be equally utilized in accordance with the embodiments disclosed herein.

The example network diagram shown in FIG. 3 is described further in U.S. patent application Ser. No. 15/804,329, assigned to the common assignee, the contents of which are hereby incorporated by reference.

It should be noted that the example network diagram shown in FIG. 3 is not limiting on the disclosed embodiments, and that the disclosed data reduction techniques may be equally applicable to other configurations and deployments of storage systems without departing from the scope of the disclosure.

FIG. 4 shows an example schematic diagram of a compute node 310 according to an embodiment. The compute node 310 includes a processing circuitry 410, a memory 420, a first network interface controller (NIC) 430, and a second NIC 440. In an embodiment, the components of the compute node 310 may be communicatively connected via a bus 450.

The processing circuitry 410 may be realized as one or more hardware logic components and circuits. For example, and without limitation, illustrative types of hardware logic components that can be used include FPGAs, ASICs, ASSPs, SOCs, general-purpose microprocessors, microcontrollers, DSPs, and the like, or any other hardware logic components that can perform calculations or other manipulations of information.

The memory 420 may be volatile (e.g., RAM, etc.), non-volatile (e.g., ROM, flash memory, etc.), or a combination thereof. In one configuration, computer readable instructions or software to implement one or more processes performed by compute node 310 may be stored in the memory 420. Software shall be construed broadly to mean any type of instructions, whether referred to as software, firmware, middleware, microcode, hardware description language, or otherwise. Instructions may include code (e.g., in source code format, binary code format, executable code format, or any other suitable format of code).

The first NIC 430 allows the compute node 310 to communicate with the storage nodes 320 via the communication fabric 330 (see FIG. 3) to provide remote direct memory access to data stored in the storage nodes 320. In an embodiment, the first NIC 430 may enable communication via RDMA protocols such as, but not limited to, Infiniband, RDMA over Converged Ethernet (RoCE), iWARP, and the like.

The second NIC 440 allows the compute node 310 to communicate with client devices (e.g., the client device 340, FIG. 3) through a communication network (e.g., the network 350, FIG. 3). Examples of such communication networks include, but are not limited to, the Internet, the world-wide-web (WWW), a local area network (LAN), a wide area network (WAN), and the like. It should be appreciated that, in some configurations, the compute node 310 may include a single NIC. This configuration is applicable when, for example, the fabric is shared.

It should be understood that the embodiments described herein are not limited to the specific architecture illustrated in FIG. 4, and other architectures may be equally used without departing from the scope of the disclosed embodiments.

The various embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such a computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiment and the concepts contributed by the inventor to furthering the art, and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for global data compression, comprising:
splitting a dataset into a plurality of blocks;
for each block of the plurality of blocks:
computing at least one similarity hash for the block;
determining, based on the at least one similarity hash, whether a similar block is found for the block, wherein a similar block for a block has a similarity hash that is similar to one of the computed at least one similarity hash for the block;
compressing the block by replacing data of the block with a reference to the similar block and a delta when a similar block is found, wherein the delta is a difference in data between the block and the similar block; and
compressing the block independently when a similar block is not found.

2. The method of claim 1, further comprising:
storing each compressed block, wherein each independently compressed block is stored with metadata, wherein the metadata includes a compression algorithm used to compress the data.

3. The method of claim 2, wherein the metadata further includes a reference count, further comprising, for each stored block:
determining, based on the reference count for the stored block, whether to delete at least one reference to the stored block, wherein it is determined to delete the at least one reference when the stored block is not being used; and
deleting the at least one reference to one of the stored blocks when it is determined to delete the at least one reference.

4. The method of claim 1, wherein the dataset is split using variable-sized chunking.

5. The method of claim 1, wherein each similar block is a reference block selected from a respective set of blocks that are similar to each other.

6. The method of claim 5, further comprising:
storing, in an index, the similarity hash computed for each of the plurality of blocks, wherein whether a similar block is found is determined based on the indexed similarity hashes.

7. The method of claim 5, wherein each reference block was received before each other block of the respective set of blocks that are similar to each other.

8. The method of claim 5, wherein each reference block has a largest size among blocks of the respective set of blocks that are similar to each other.

9. The method of claim 1, further comprising:
normalizing the dataset, wherein the normalized dataset is split into the plurality of blocks.

10. The method of claim 9, wherein the dataset includes compressed data, wherein normalizing the dataset further comprises:
determining a compression technique used to compress the data of the dataset;
determining, based on the compression technique, a decompression technique; and
decompressing the compressed data of the dataset using the decompression technique.

11. A non-transitory computer readable medium having stored thereon instructions for causing a processing circuitry to execute a process, the process comprising:
splitting a dataset into a plurality of blocks;
for each block of the plurality of blocks:
computing at least one similarity hash for the block;
determining, based on the at least one similarity hash, whether a similar block is found for the block, wherein a similar block for a block has a similarity hash that is similar to one of the computed at least one similarity hash for the block;
compressing the block by replacing data of the block with a reference to the similar block and a delta when a similar block is found, wherein the delta is a difference in data between the block and the similar block; and
compressing the block independently when a similar block is not found.

12. A system for global data compression, comprising:
a processing circuitry; and
a memory, the memory containing instructions that, when executed by the processing circuitry, configure the system to:
split a dataset into a plurality of blocks;
for each block of the plurality of blocks:
compute at least one similarity hash for the block;
determine, based on the at least one similarity hash, whether a similar block is found for the block, wherein a similar block for a block has a similarity hash that is similar to one of the computed at least one similarity hash for the block;
compress the block by replacing data of the block with a reference to the similar block and a delta when a similar block is found, wherein the delta is a difference in data between the block and the similar block; and
compress the block independently when a similar block is not found.

13. The method of claim 12, further comprising:
storing each compressed block, wherein each independently compressed block is stored with metadata, wherein the metadata includes a compression algorithm used to compress the data.

14. The method of claim 13, wherein the metadata further includes a reference count, further comprising, for each stored block:
determining, based on the reference count for the stored block, whether to delete at least one reference to the stored block, wherein it is determined to delete the at least one reference when the stored block is not being used; and
deleting the at least one reference to one of the stored blocks when it is determined to delete the at least one reference.

15. The method of claim 12, wherein the dataset is split using variable-sized chunking.

16. The method of claim 12, wherein each similar block is a reference block selected from a respective set of blocks that are similar to each other.

17. The method of claim 16, further comprising:
storing, in an index, the similarity hash computed for each of the plurality of blocks, wherein whether a similar block is found is determined based on the indexed similarity hashes.

18. The method of claim 16, wherein each reference block was received before each other block of the respective set of blocks that are similar to each other.

19. The method of claim 16, wherein each reference block has a largest size among blocks of the respective set of blocks that are similar to each other.

20. The method of claim 12, further comprising:
normalizing the dataset, wherein the normalized dataset is split into the plurality of blocks.

21. The method of claim 20, wherein the dataset includes compressed data, wherein normalizing the dataset further comprises:
determining a compression technique used to compress the data of the dataset;
determining, based on the compression technique, a decompression technique; and
decompressing the compressed data of the dataset using the decompression technique.
